(19) United States
(12) Patent Application Publication
(10) Pub. No.: US 2009/0232965 A1
(43) Pub. Date: Sep. 17, 2009

(54) Method and apparatus for producing aligned carbon nanotube aggregate

(76) Inventors: Kenji Hata, Ibaraki (JP); Satoshi Yasuda, Ibaraki (JP); Motoo Yumura, Ibaraki (JP)

Correspondence Address: WENDEROTH, LIND & PONACK, L.L.P., 1030 15th Street, N.W.,, Suite 400 East, Washington, DC, 20005-1503, US

(21) Appl. No.: 12/379,803

(22) Filed: Mar. 2, 2009

(30) Foreign Application Priority Data
Feb. 29, 2008 (JP) 2008-051321

(51) Int. Cl. C23C 16/52; B05C 11/00

(52) U.S. Cl. 427/8; 118/665

(57) ABSTRACT

The present invention provides a method and an apparatus capable of mass-producing an aligned CNT aggregate of a desired height through automatic control of a CVD apparatus according to a growth height of the aligned CNT aggregate. According to the present invention, an aligned carbon nanotube aggregate growing on a substrate is irradiated with a parallel ray, and the size of a resulting shadow is measured with a measurement section using a telecentric optical system, which acts as if it has an infinite focal length, so as to detect, in real time, a growth height of the aligned carbon nanotube aggregate being synthesized, and the synthesis of the aligned carbon nanotube aggregate is terminated when the growth height of the aligned carbon nanotube aggregate reaches a predetermined state.

### TECHNICAL FIELD

The present invention relates to a method and an apparatus for producing an aligned carbon nanotube aggregate, capable of conveniently monitoring a growth state of an aligned carbon nanotube aggregate, and mass-producing an aligned carbon nanotube aggregate of a desired height at high efficiency. As used herein, the “aligned carbon nanotube aggregate” refers to a plurality of carbon nanotubes (for example, a density of at least 5×10¹¹ tubes/cm²) being assembled into a block, a film, or a bundle by van der Waals force.

### BACKGROUND ART

Over the last years, carbon nanotubes (also referred to as “CNT” hereinafter), with their unique physical, chemical, and mechanical properties, have gained a great deal of attention. Of particular interest is the aligned CNTs formed by a plurality of CNTs aligning in one direction, which have many superior properties such as high purity, large specific surface area, high vertical alignment characteristic, and good extensibility. For this reason, there is movement toward application of aggregates of such CNTs in areas of, for example, actuators, biosensors, capacitor materials, high conductive materials, and material storages.

Use of such aligned CNT aggregates as industrial material in a wide range of applications requires considerations to the fact that the properties of the aligned CNT aggregate, including electrical, chemical, and mechanical properties, heat conductivity, and specific surface area, are greatly influenced by the height of the aligned CNT aggregate. It is therefore necessary to realize a technique capable of efficiently mass-producing an aligned CNT aggregate of a desired height suitable for different applications.

There is a related technique applicable to mass-production of the aligned CNT aggregate by a chemical vapor deposition apparatus (also referred to as “CVD apparatus” hereinafter). In this technique, optical techniques such as interference, absorption, diffraction, and projection are used to observe a growth state of the aligned CNT aggregate in real time, as described in D. B. Geohegan, et al., In situ Growth Rate Measurements and Length Control During Chemical Vapor Deposition of Vertically Aligned Multiwall Carbon Nanotubes, Applied Physics Letters, Vol. 83, p. 1851-1853, 2003 (Non-Patent Document 1), D-H. Kim, et al., Dynamic Growth Rate Behavior of a Carbon Nanotube Forest Characterized by In situ Optical Growth Monitoring, Nano Letters, Vol. 3, No. 6, p. 863-865, 2003 (Non-Patent Document 2), S. Maruyama, et al., Growth Process of Vertically Aligned Single-Walled Carbon Nanotubes, Chemical Physics Letters, 403, p. 320-323, 2005 (Non-Patent Document 3), and L. M. Dell'Acqua-Bellavitis, et al., Kinetics for the Synthesis Reaction of Aligned Carbon Nanotubes: A Study Based on In situ Diffractography, Nano Letters, 4, p. 1613-1620, 2004 (Non-Patent Document 4).

However, the methods described in these publications fail to provide a narrow measurable height range, and cannot accurately measure a height of the aligned CNT aggregate with sufficient resolution in the order of millimeters. Further, the technique requires the optical system of the measurement device to be readjusted in every synthesis, making the measurement inconvenient and the technique unsuitable for mass-production facilities.

Recently, a technique was developed that measures a height of the aligned CNT aggregate in units of millimeters based on image data obtained through an optical camera, as described in Itaru Gunjishima, et al., In situ Optical Imaging of Carbon Nanotube Growth, Japanese Journal of Applied Physics, Vol. 46, No. 5A, p. 3149-3151, 2007 (Non-Patent Document 5), Itaru Gunjishima, et al., In situ Growth Rate Control of Carbon Nanotubes by Optical Imaging Method, Applied Physics Letters, Vol. 91, p. 193102-1-193102-3, 2007 (Non-Patent Document 6), and A. J. Hart, et al., Desktop Growth of Carbon-Nanotube Monoliths with In situ Optical Imaging, Small, 3, No. 5, p. 772-777, 2007 (Non-Patent Document 7).

However, the technique described in these publications requires scale calibration of image data and readjustments of focal length in every synthesis to accommodate a change in distance (measurement distance) between the measured aligned CNT aggregate as an object to be measured and the lens in each synthesis. That is, the technique makes no improvement to make it suitable for mass-production facilities. Further, in a common optical camera, since the lens magnification and an angle of view (field of view) are inversely proportional, increasing the resolution narrows the measurable range, and conversely, providing a wider measurable range results in lower resolutions. That is, a single lens system cannot provide a high resolution and a wide field of view at the same time, making it difficult to accommodate to production of aligned CNT aggregates of a wide height range. Further, by the carbon impurities that gradually adhere to the inner side of the apparatus to form stains, the transmittance of light through the reactor decreases over time. This makes it difficult to externally observe the growth state of the aligned CNT aggregate in real time over extended time periods using a common optical camera.

### DISCLOSURE OF INVENTION

In sum, the following problems are encountered when the traditional techniques are used to monitor the growth height of the aligned CNT aggregate.

1. Stains formed inside the reactor by the adhesion of carbon impurities generated by the pyrolysis of the feedstock material make it difficult to monitor the growth height of the aligned CNT aggregate.

2. The monitor unit needs to be readjusted for every different synthesis condition of the aligned CNT aggregate, making it difficult to continuously synthesis the CNT aggregate at high efficiency.

3. A high-resolution and wide-range measurement of a growth state of the aligned CNT aggregate is difficult to achieve.

The present invention was made to overcome the drawbacks of the traditional techniques, and a main object of the invention is to provide a monitor unit, capable of in situ real-time monitoring of the growth height of the aligned CNT aggregate, which can monitor the growth height of the aligned CNT aggregate over extended time periods regardless of the stains formed inside the reactor, without requiring readjustments during a continuous synthesis of the aligned CNT aggregate, and which can perform a wide-range and high-resolution measurement of the growth height of the aligned CNT aggregate. The invention also provides a method and an apparatus for mass-producing an aligned CNT aggregate of a desired height, by installing the high-performance monitor unit in a CVD apparatus, which is automatically controlled according to the growth height of the aligned CNT aggregate based on the output of the monitor unit sent to a synthesis process control computer of the CVD apparatus.

In order to achieve the foregoing objects, in one aspect of the present invention, there is provided a method for producing an aligned carbon nanotube aggregate, the method including: exposing an aligned carbon nanotube aggregate 11 growing on a substrate 2 to a parallel ray; measuring a size of a resulting shadow with a measurement section 13 using a telecentric optical system, so as to detect a growth height of the aligned carbon nanotube aggregate; and terminating the synthesis of the aligned carbon nanotube aggregate when the detected value reaches a predetermined state. As used herein, the “shadow” of the aligned carbon nanotube aggregate refers to an image formed by the aligned carbon nanotubes due to obstruction of a parallel ray of visible light shone thereon.

In another aspect of the present invention, there is provided an apparatus for producing an aligned carbon nanotube aggregate, the apparatus including: a light irradiator 12 to expose an aligned carbon nanotube aggregate 11 growing on a substrate 2 to a parallel ray L; a measurement section 13 to measure a size of a resulting shadow through a telecentric optical system; and a controller (CPU 20) to control synthesis conditions of the aligned carbon nanotube aggregate based on an output of the measurement section, the controller terminating the synthesis of the aligned carbon nanotube aggregate when the measurement section detects that a growth height of the aligned carbon nanotube aggregate reaches a predetermined state.

Since the measurement section uses the telecentric optical system that acts as if it has an infinite focal length, no readjustments are required for the optical system during a continuous synthesis. Further, since the light emitted by the light irradiator is a parallel ray, the reduction in the transmittance of light due to the stains formed by carbon impurities that gradually adheres inside the reactor during CNT growth does not have a large effect. Further, the synthesis process can be automatically controlled according to the measured growth height output.

With the foregoing technical measures and practice, the present invention enables accurate, automatic control of the CVD apparatus for the synthesis of the aligned CNT aggregate. This is highly advantageous in realizing high efficient mass-production of aligned CNT aggregates of a desired height.

### BRIEF DESCRIPTION OF DRAWINGS

FIG. 1 is a plan view schematically showing a CNT producing apparatus used by the present invention.

FIG. 2 is a side view schematically showing a CNT producing apparatus of the present invention provided with a light irradiator, and a measurement section using a telecentric optical system.

FIG. 3 is a flow chart schematizing a CNT producing method of the present invention.

FIG. 4 is a diagram representing growth curves of an aligned CNT aggregate plotted by varying a water content and synthesis temperature.

FIG. 5 is a diagram representing a growth curve of an aligned CNT aggregate plotted under certain conditions.

FIG. 6 is a diagram representing a growth curve of an aligned CNT aggregate as reported in Non-Patent Document 7.

FIG. 7 shows a photograph of an aligned CNT aggregate synthesized under the automatic control of the present invention.

FIG. 8 shows a photographic image taken by a scanning electron microscope (SEM), measuring heights of aligned CNT aggregates synthesized under the automatic control of the present invention.

FIG. 9 is a graph representing errors of the SEM measured, actual height of an aligned CNT aggregate against the target value.

FIG. 10 is graph representing changes in height of an aligned CNT aggregate as a function of growth time.

### PREFERRED EMBODIMENT OF THE INVENTION

The following specifically describes a preferred embodiment of the present invention with reference to the accompanying drawings.

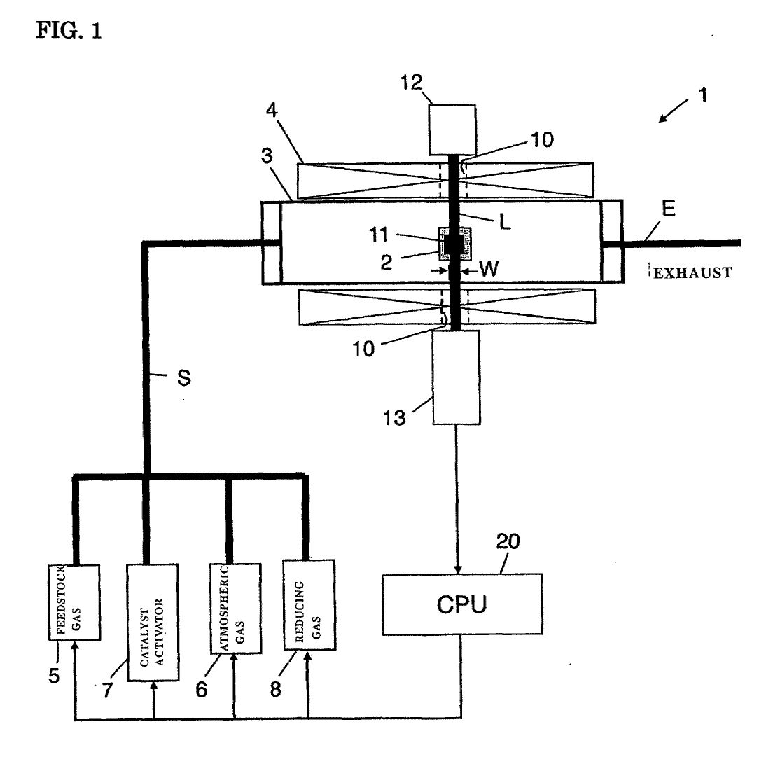

FIG. 1 shows an example of a CVD apparatus used by the present invention. A CVD apparatus 1 includes a tubular reaction chamber 3, made from a translucent material such as fused quartz, accommodating a substrate 2 carrying a metal catalyst; a heater 4 provided around the reaction chamber 3; a supply pipe S connected to a wall at one end of the reaction chamber 3 to supply a feedstock gas 5, an atmospheric gas 6, a catalyst activator 7, and a reducing gas 8; and an exhaust pipe E connected to a wall at the other end of the reaction chamber 3. Though not shown, a control unit, including devices such as a flow control valve and a pressure control valve, is provided at an appropriate place of the CVD apparatus 1.

The heater 4 has a light guiding path 10, suitably provided to permit irradiation and detection of light by an optical system (described later), enabling in situ real-time measurements of a growth height of an aligned CNT aggregate in the reaction chamber 3. Preferably, the light guiding path 10 is provided using a material of properties sufficient to transmit the light emitted by a light irradiator (described later) and to resist the synthesis temperature, in addition to being capable of maintaining a uniform heat distribution inside the reaction chamber 3. A preferable example of such material is fused quartz.

Note that the foregoing CVD apparatus 1 is merely an example, and the CVD apparatus to which the present invention is applicable is not just limited to the one described above.

The following describes a monitor unit used to monitor a growth height of an aligned CNT aggregate 11 synthesized on the substrate 2. The monitor unit includes a light irradiator 12 that emits a parallel ray L of an appropriate wavelength (for example, visible light), and a measurement section 13 that detects the emitted light to measure the height of the aligned CNT aggregate 11.

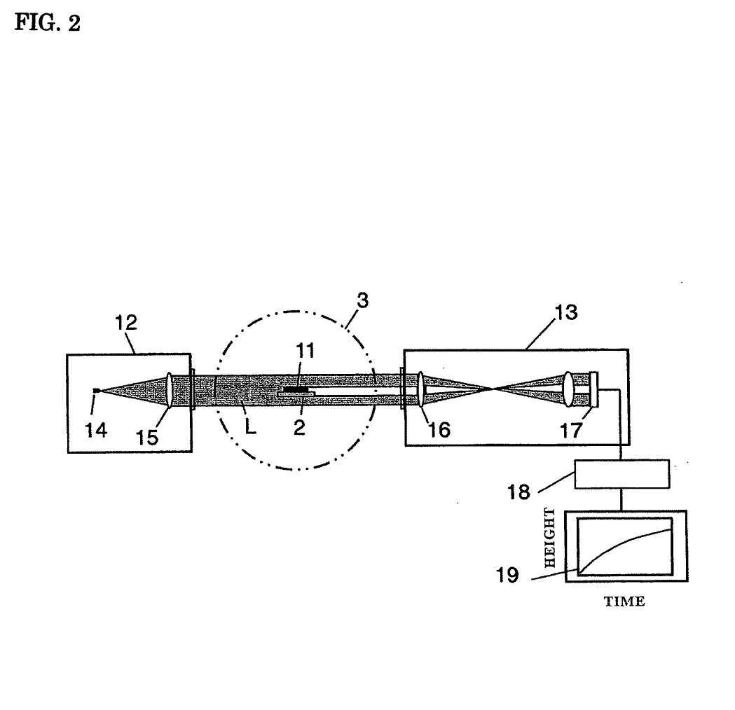

As shown in FIG. 2, the light irradiator 12 includes a light source 14 using, for example, an LED, and a collimater lens 15. The light from the light source 14 becomes a uniform parallel ray L through the collimater lens 15, and falls on the substrate 2 disposed at an appropriate place inside the reaction chamber 3, and on the aligned CNT aggregate 11 grown on the catalyst-coated surface of the substrate 2. Preferably, the irradiation direction of parallel ray L is orthogonal to the aligning direction of the aligned CNT aggregate 11 growing on the substrate 2. The light source 14 is not limited to an LED.

The measurement section 13 includes a condenser lens 16 of the telecentric optical system, a photodetector 17 using, for example, a CCD element, and a signal processor 18 that processes signals produced by photoelectric conversion in the photodetector 17. The measurement section 13 outputs a sum of the thickness of the substrate 2 and the growth height of the aligned CNT aggregate 11, based on an intensity signal produced by the photodetector 17 upon projection of a shadow image created by the parallel ray L falling on the substrate 2 and the aligned CNT aggregate 11.

During CNT synthesis, the thickness of the substrate 2 remains the same, and only the height of the aligned CNT aggregate 11 increases as the CNT aggregate grows. Thus, by subtracting the thickness of the substrate 2 from the varying output values of the photodetector 13 over a time course, a time-dependent height change, or the growth state, of the aligned CNT aggregate 11 can be monitored in real time on a monitor 19.

Signals concerning the height of the aligned CNT aggregate 11, produced by the measurement section 13, are sent to a CPU 20 (FIG. 1), which incorporates synthesis process control software for controlling devices such as the flow control valve and the pressure control valve. In the CPU 20, the value of actual height or growth rate of the aligned CNT aggregate is compared with the target value of height or growth rate set on the software. When the actual value has reached the target value, the CPU 20 sends a predetermined control signal to devices such as the flow control valve and the pressure control valve, thereby automatically controlling the ON/OFF of these devices.

In this manner, the present invention automatically controls the supply of feedstock gas 5 and other materials according to the growth state of the aligned CNT aggregate 11 in the reaction chamber 3, making it possible to automatically produce an aligned CNT aggregate 11 of a desired height.

Preferably, the light irradiator 12 and the measurement section 13 are disposed some distance apart from the heater 4 to avoid overheating. However, since the resolution lowers when the measurement section 13 is too far apart from the substrate 2 and the aligned CNT aggregate 11, it is preferable that the light irradiator 12 and the measurement section 13 be separated from the heater 4 by such a distance sufficient to provide enough resolution for practical purposes, and to prevent the applied heat from adversely affecting the operation of the light irradiator 12 and the measurement section 13. In this embodiment, the substrate 2 and the aligned CNT aggregate 11 are separated from the measurement section 13 by a distance of about 5 to 50 cm.

The characteristic of the telecentric optical system, aside from offering high-accuracy measurement, is that a change in the distance separating the condenser lens 16 from the substrate 2 and the aligned CNT aggregate 11 does not accompany any change in lens magnification and focal length. This eliminates the need to readjust the optical system every time the distance between the condenser lens 16, and the substrate 2 and the aligned CNT aggregate 11 is changed for each synthesis.

In a common CVD apparatus, the carbon impurities generated by the pyrolysis of the feedstock gas during the CNT synthesis produce stains by adhering to the inner surfaces of the reaction chamber. Accordingly, in a prolonged synthesis process, it is difficult to capture the CNT growth state using an optical camera provided outside the reaction chamber. In the present invention, the light irradiator 12, emitting a parallel ray L of, for example, visible light, is disposed on the opposite side from the measurement section 13. In this way, the parallel ray L emitted by the light irradiator 12 passes through the adhered carbon impurity stains, and forms a shadow image of the CNT aggregate 11, grown on the substrate 2, on the photodetector 17. Thus, with the configuration of the present invention, the growth state of the aligned CNT aggregate 11 can be monitored for extended time periods, without the influence of stains caused by the adhesion of carbon impurities generated inside the reaction chamber 3.

The width of parallel ray L emitted by the light irradiator 12, as shown by dimension W in FIG. 1, needs to be set such that the shadow image of the substrate 2 and the aligned CNT aggregate 11 clearly forms on the photodetector 17. In this embodiment, the width of parallel ray L is 7 mm. An optimum width should be selected according to intended use. For example, by increasing the width W of parallel ray L, the photodetector 17, with a CCD camera in place, can display an image of the substrate 2 and the aligned CNT aggregate 11.

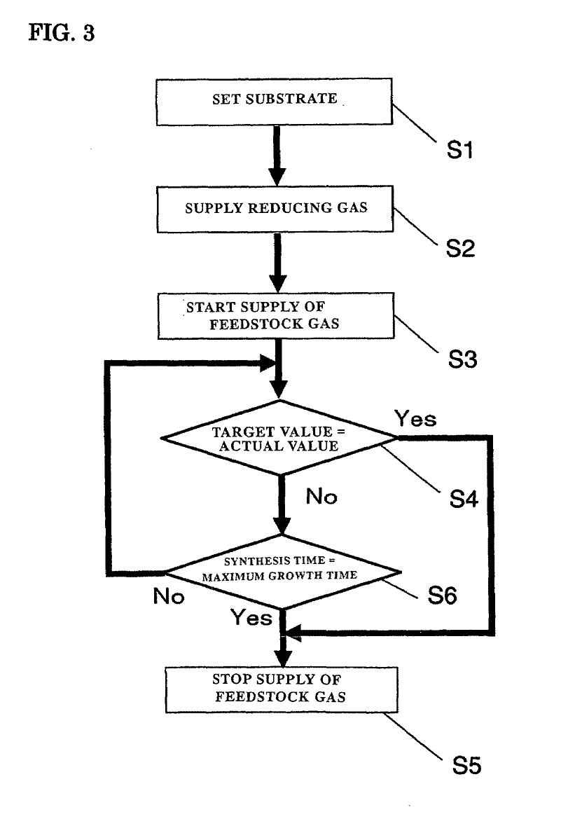

With reference to FIG. 3, the following describes the steps for producing the aligned CNT aggregate 11 using the CVD apparatus 1.

First, the substrate 2 is placed in the reaction chamber 3 and disposed on a predetermined position (S1). Then, the atmospheric gas 6, in mixture with the reducing gas 8, is supplied to the reaction chamber 3, causing the reducing gas 8 to contact the metal catalyst film on the substrate 2 for a predetermined time period (S2). This processes the metal catalyst into fine particles suitable for CNT growth.

Next, the reaction chamber 3 is charged with the atmospheric gas 6, the feedstock gas 5, and optionally, the catalyst activator 7 to grow the aligned CNT aggregate 11 (S3). In this growing step, the height of the aligned CNT aggregate 11 is monitored in real time with the light irradiator 12 and the measurement section 13.

During the growth of the aligned CNT aggregate 11, the current and previous heights are repeatedly compared with the target value at an appropriate sampling frequency, and when it is detected that the value of height or growth rate is equal to the target value set on the synthesis process control software (Yes in S4), the control valves are immediately closed to stop the supply of the feedstock gas 5 and other materials into the reaction chamber 3 (S5). This stops the growth of aligned CNT aggregate 11.

Without any control, the apparatus keeps supplying the feedstock gas 5 and other materials into the reaction chamber 3 even when, for some reason, the actual value of the height or growth rate of the aligned CNT aggregate 11 under real-time measurement does not reach the target value set on the synthesis process control software. To prevent this, the synthesis process control software has a maximum growth time. Specifically, when the maximum growth time has elapsed before the monitored actual value of the height or growth rate of the aligned CNT aggregate 11 reaches the target value set on the synthesis process control software (Yes in S6), the supply of materials such as the feedstock gas 5 is forcibly terminated to avoid unnecessary synthesis of the aligned CNT aggregate 11.

Regarding the synthesis mechanism of the aligned CNT aggregate, no detailed explanation will be given because it is known and does not directly relate to the nature of the present invention. The aligned CNT aggregate can be produced by the process of growing large numbers of vertically aligned CNTs in the presence of water in a reaction atmosphere, as previously proposed by the applicant of the present invention (see, for example, Kenji Hata et al., Water-Assisted Highly Efficient Synthesis of Impurity-Free Single-Walled Carbon Nanotubes, SCIENCE, Nov. 19, 2004, vol. 306, p. 1362-1364, and PCT/JP2008/51749 specification).

The following more specifically describes the present invention based on examples and comparative examples.

### Example 1

An assessment was made regarding the ability of the present invention to continuously and conveniently measure the height of the aligned CNT aggregate without having the need to readjust the optical system for different synthesis conditions.

An aligned CNT aggregate was grown on a substrate previously coated with a catalyst coating (thickness: Al₂O₃, 40 nm; Fe, 1.0 nm). The growth was promoted under the following conditions.

Feedstock gas: ethylene; feed rate, 100 sccm

Atmospheric gas: helium/hydrogen mixture gas; feed rate, 1,000 sccm

Pressure: atmospheric pressure

Water content (abundance): 36, 143, 250, 357, 463, 570 ppm

Reaction temperature: 700, 725, 750, 775, 800° C.

Reaction time: 10 minutes

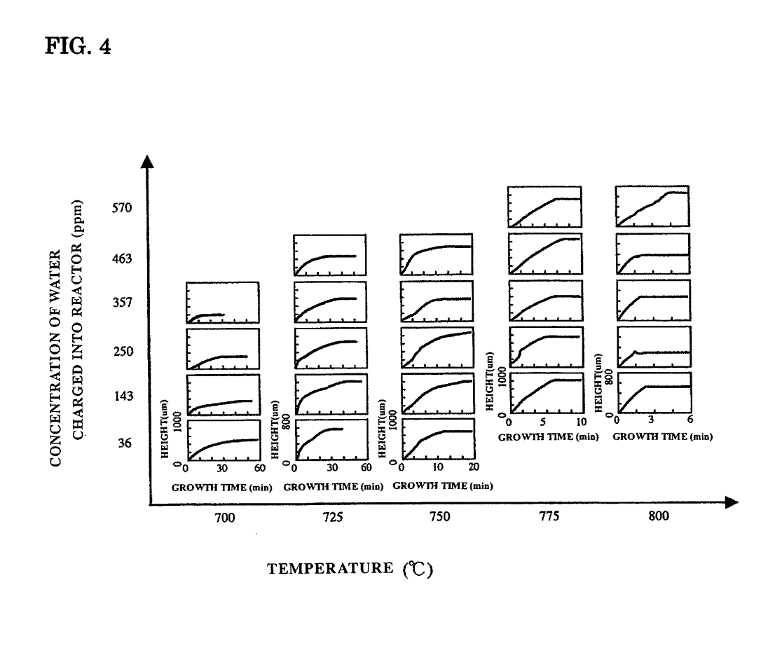

FIG. 4 shows growth curves of the aligned CNT aggregate when it was continuously synthesized 24 times in full automation by varying the temperature and water concentration conditions in the steps above. As shown in the figure, it was possible to continuously measure the growth state in each synthesis with good reproducibility, without any readjustment of the optical system. That is, the experiment confirmed the ability of the present invention to continuously and conveniently measure the height of the aligned CNT aggregate without having the need to readjust the optical system for different synthesis conditions.

### Example 2

An assessment was made regarding the ability of the present invention to continuously and conveniently measure the height of the aligned CNT aggregate over extended time periods with high resolution and over a wide dynamic range.

An aligned CNT aggregate was grown on a substrate coated with a catalyst coating (thickness: Al₂O₃, 40 nm; Fe, 1.0 nm). The growth was promoted under the following conditions.

Feedstock gas: ethylene; feed rate, 10 sccm

Atmospheric gas: helium/hydrogen mixture gas; feed rate, 1,000 sccm

Pressure: atmospheric pressure

Water content (abundance): 36 ppm

Reaction temperature: 750° C.

Reaction time: 80 minutes

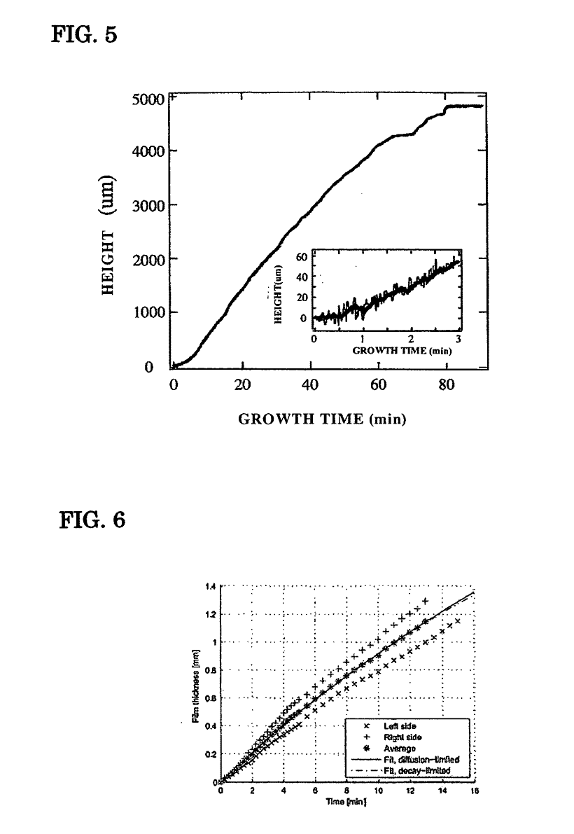

FIG. 5 shows a relationship between the height of the aligned CNT aggregate and growth time under the foregoing conditions. The insert in FIG. 5 is a growth curve observed at an early stage of growth, in which the sampling frequency at the measurement point is 1 Hz. It can be seen from the insert that the measured height values fluctuate over a range of about ±6 μm (two standard deviations σ; for convenience, the denotation “um” in the drawings is used to designate “μm”). The fluctuations are attributed to the heat fluctuation in the atmosphere of the optical path, and small vibrations occurring at the mount of the substrate 2, and at the apparatus itself. By in situ filtering, measurements can be made with fluctuations of about ±1 μm (two standard deviations σ). The result showed that an apparatus of the present invention indeed has high resolution.

Regarding the measurement range, the growth curve can be continuously monitored over a 5 mm length, as shown by the growth curve of FIG. 5. That is, the experiment showed that an apparatus of the present invention enables a high-resolution (about 1 μm) and wide-range (5 mm or more) measurement, confirming the wide dynamic range of an apparatus of the present invention.

The maximum measurable range of an apparatus of the present invention depends on the lens size of the telecentric optical system used for the measurement section. In this example, the actual maximum measurable range was 30 mm. The measurable range can be increased by using a larger telecentric optical system.

In this example, after 80 minutes of synthesis, the reaction chamber had a large amount of carbon impurities adhered to the inner surfaces, an amount too large to view inside the chamber. However, despite the low transmittance caused by the stains, the light from the light irradiator produced a clear projection image on the photodetector, making it possible to plot a growth curve of the aligned CNT aggregate over a 5 mm length during the 80-munite synthesis. The experiment showed that an apparatus of the present invention, by the provision of the light irradiator, is capable of measuring the height of the aligned CNT aggregate for extended time periods, regardless of the stains formed on the inner surfaces of the reaction chamber.

In contrast, when the technique described in, for example, Non-Patent Document 7 is used, the image gradually becomes unclear as the carbon impurities generated by CNT synthesis produce stains by adhering to the inner surface of the quartz tube, preventing the height measurement after about 15 minutes of growth (see FIG. 6). Further, with the measurement system using an optical camera, a high-resolution and wide-range measurement of the growth curve of the aligned CNT aggregate is not possible unless the optical lens is exchanged or adjusted.

### Example 3

An assessment was made regarding the ability of the present invention to produce an aligned CNT aggregate of a desired height with high accuracy and high reproducibility.

An aligned CNT aggregate was grown on a substrate previously coated with a catalyst coating (thickness: Al₂O₃, 40 nm; Fe, 1.0 nm). The growth was promoted under the following conditions.

Feedstock gas: ethylene; feed rate, 100, 20 sccm

Atmospheric gas: helium/hydrogen mixture gas; feed rate, 1,000 sccm

Pressure: atmospheric pressure

Water content (abundance): 250 ppm

Reaction temperature: 750° C.

Reaction time: 10 minutes

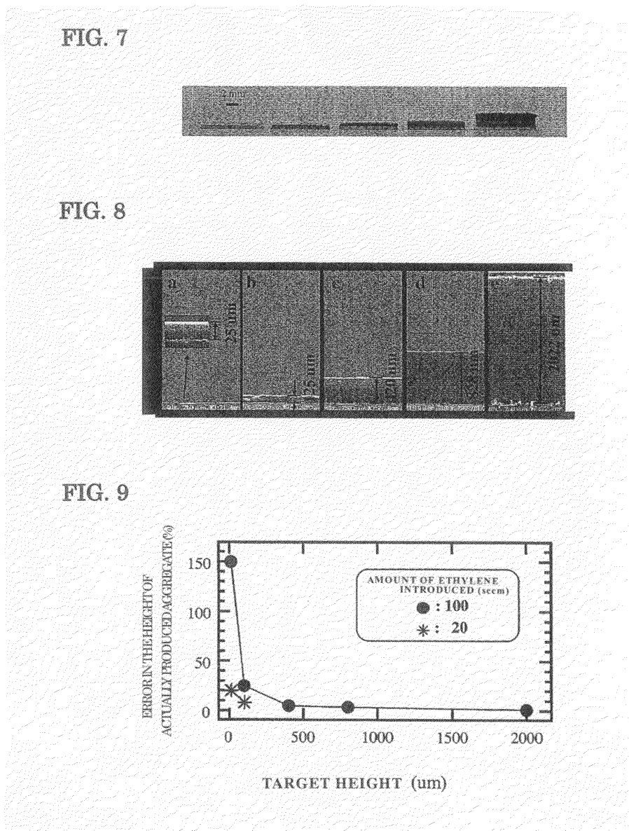

FIG. 7 shows a photograph of aligned CNT aggregates, respectively corresponding to the target values of 10, 100, 400, 800, and 2,000 μm, synthesized by stopping the supply of feedstock gas when signals indicative of the actual growth height reached these values. In FIG. 8, a to e show results of actual height measurements performed by observing the cross section of each aligned CNT aggregate with a scanning electron microscope (SEM). The actual growth heights were 25, 125, 420, 828, and 2,022 μm, respectively corresponding to the foregoing target values.

FIG. 9 represents a graph showing errors of the SEM measured, actual heights of the aligned CNT aggregate plotted against the target values. As can be seen from FIG. 9, the errors are +150% and +25% against the target values of 10 μm and 100 μm, respectively. That is, the error in the actual height of the aligned CNT aggregate increases for smaller target values. In contrast, in a target value range of 400 μm or more, the error is substantially constant at or below +5%, suggesting that accurate, automated fabrication of an aligned CNT aggregate of a desired height is possible above a certain height.

The large errors in a small target value range is believed to be due to the continuous CNT growth facilitated by the residual feedstock gas that remains in the reaction chamber after stopping the supply of the feedstock gas. It can therefore be said that the error can be reduced by reducing the flow rate of the feedstock gas supplied into the reaction chamber to thereby reduce the amount of feedstock gas remaining in the reaction chamber after stopping the supply of the feedstock gas.

Based on this reasoning, growth was promoted with a 20 sccm supply of the feedstock gas. This was found to greatly reduce error, as indicated by asterisk in FIG. 9.

Other than this technique to reduce error by preventing the feedstock gas from remaining in the reaction chamber after stopping the supply of the feedstock gas, error can also be reduced effectively, for example, by quickly eliminating the residual feedstock gas by supplying large amounts of atmospheric gas immediately after stopping the supply of the feedstock gas, or by reducing the feed rate of the feedstock gas as the actual value approaches the target value.

The foregoing results showed that an apparatus of the present invention, by automatically controlling the synthesis process of the CVD apparatus based on height signals of the aligned CNT aggregate, is capable of producing an aligned CNT aggregate of a desired height with high accuracy and high reproducibility.

### Example 4

An apparatus of the present invention, performing automatic control for the synthesis process of the CVD apparatus based on height signals of the aligned CNT aggregate, is described below in regard to fabrication of an aligned CNT aggregate having a large specific surface area, enabled by stopping the supply of the feedstock gas and terminating the synthesis process when the height of the aligned CNT aggregate has reached a predetermined value, or when the growth of the aligned CNT aggregate has stopped.

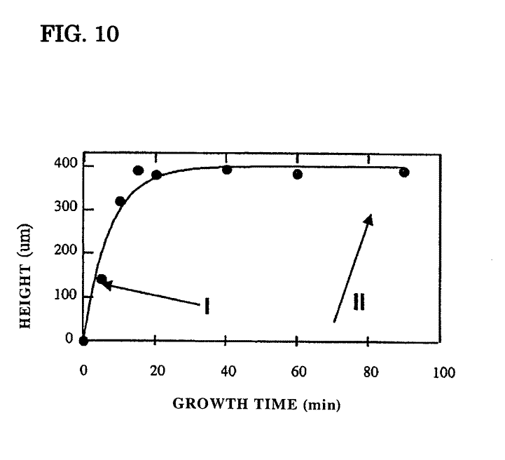

FIG. 10 is a plot of height versus growth time of the aligned CNT aggregate measured under certain conditions. As shown in the graph, the growth stops after about 20 minutes of synthesis. In this example, the aligned CNT aggregate after a 5-minute synthesis (indicated by “I” in FIG. 10) had a specific surface area of 1,230 m²/g. When the feedstock gas was continuously supplied for about 70 minutes after stopping the growth (indicated by “II” in FIG. 10), the specific surface area dramatically reduced to 176 m²/g.

This result indicates that the carbon generated by the pyrolysis of the feedstock gas, when exposed to the previously synthesized aligned CNT aggregate, adheres to the surfaces of the CNTs and reduces the specific surface area. The result therefore suggests that, for the synthesis of an aligned CNT aggregate having a large specific surface area, the synthesis needs to be terminated immediately when the CNT aggregate has reached a desired height, or when the growth has stopped.

In the present invention, the in situ real-time measurement of the aligned CNT aggregate height enables automatic control of the CVD apparatus based on the detected value. The automatic control makes it possible to immediately terminate the synthesis when the aligned CNT aggregate has reached a desired height, or when the growth has stopped. As a result, carbon adhesion is minimized, and an aligned CNT aggregate having a large specific surface area can be produced.

What is claimed is:

1. A method for producing an aligned carbon nanotube aggregate, the method comprising:
exposing an aligned carbon nanotube aggregate growing on a substrate to a parallel ray;
measuring a size of a resulting shadow with a measurement section using a telecentric optical system, so as to detect a growth height of the aligned carbon nanotube aggregate; and
terminating the synthesis of the aligned carbon nanotube aggregate when the detected value reaches a predetermined state.

2. An apparatus for producing an aligned carbon nanotube aggregate, the apparatus comprising:
a light irradiator to shine a parallel ray on an aligned carbon nanotube aggregate growing on a substrate;
a measurement section to measure a size of a resulting shadow through a telecentric optical system; and
a controller to control synthesis conditions of the aligned carbon nanotube aggregate based on an output of the measurement section,
the controller terminating the synthesis of the aligned carbon nanotube aggregate when the measurement section detects that a growth height of the aligned carbon nanotube aggregate reaches a predetermined state.
